(19) United States
(12) Patent Application Publication
(10) Pub. No.: US 2026/0206473 A1
(43) Pub. Date: Jul. 16, 2026

(54) DISPLAY PANEL AND DISPLAY DEVICE

(71) Applicant: HKC CORPORATION LIMITED, Shenzhen (CN)

(72) Inventors: Qin LIANG, Shenzhen (CN); Yangling TANG, Shenzhen (CN); Zhisheng XIE, Shenzhen (CN); Xiufeng ZHOU, Shenzhen (CN); Haijiang YUAN, Shenzhen (CN)

(21) Appl. No.: 19/424,241

(22) Filed: Dec. 18, 2025

(30) Foreign Application Priority Data
Jan. 8, 2025 (CN) 202510028195.9

(51) Int. Cl. H10K 59/80; H10K 59/122; H10K 102/00

(52) U.S. Cl. CPC H10K 59/879; H10K 59/122; H10K 59/873; H10K 59/8792; H10K 2102/351

(57) ABSTRACT

A display panel and a display device are disclosed. The display panel includes a substrate, a pixel defining layer, multiple display sub-pixels, multiple anti-peeping sub-pixels, an encapsulation layer, and multiple light-shielding layers. The encapsulation layer includes an organic encapsulation layer and a first inorganic encapsulation layer. The first inorganic encapsulation layer is disposed on a side of the organic encapsulation layer facing away from the substrate. Within the area where each anti-peeping sub-pixel is located, at least one refractive surface is disposed on a side of the organic encapsulation layer facing towards the first inorganic encapsulation layer. The at least one refractive surface is configured to refract part of the light emitted from the anti-peeping sub-pixel toward the corresponding light-shielding layer, so that the light exits from at least one adjacent aperture region.

### CROSS-REFERENCE TO RELATED APPLICATIONS

The present application claims the priority and benefit of Chinese patent application number 2025100281959, titled "Display Panel and Display Device" and filed January 08, 2025 with China National Intellectual Property Administration, the entire contents of which are incorporated herein by reference.

### TECHNICAL FIELD

The present application relates to the field of display technologies, and more particularly to a display panel and a display device.

### BACKGROUND

The description provided in this section is intended for the mere purpose of providing background information related to the present application but does not necessarily constitute prior art.

Organic light-emitting diode (OLED) display technology is gradually maturing, and as a self-emissive display technology, it is being increasingly applied in products. With the growing concern for personal privacy in modern society, the anti-peeping function of the display panel has become an essential feature of products. Therefore, OLED anti-peeping technology has also become a hot topic of discussion in recent years.

In one anti-peeping technology that increases anti-peeping pixels, an anti-peeping sub-pixel may be disposed between two adjacent display sub-pixels. The anti-peeping sub-pixel emits anti-peeping light rays that interfere with the display effect at a wide viewing angle, thereby achieving an anti-peeping effect. However, the utilization rate of the anti-peeping light rays is low, resulting in a poor anti-peeping effect.

### SUMMARY

It is therefore one purpose of the present application to provide a display panel and a display device. By disposing at least one refractive surface, the utilization rate of anti-peeping light rays at a side viewing angle is improved, thereby enhancing the anti-peeping effect of the display panel.

The present application discloses a display panel. The display panel includes a plurality of aperture regions and a plurality of non-aperture regions. The display panel further includes a substrate, a pixel defining layer, a plurality of display sub-pixels, a plurality of anti-peeping sub-pixels, an encapsulation layer, and a plurality of light-shielding layers. The pixel defining layer is disposed on the substrate and located within the plurality of non-aperture regions. The plurality of display sub-pixels are respectively disposed in the plurality of aperture regions. Two adjacent display sub-pixels are separated by the pixel defining layer. The plurality of anti-peeping sub-pixels are respectively disposed in the plurality of non-aperture regions. At least one of the anti-peeping sub-pixels is disposed within each single pixel. Each anti-peeping sub-pixel is separated from each adjacent display sub-pixel by the pixel defining layer. The encapsulation layer is disposed on the pixel defining layer, the plurality of display sub-pixels, and the plurality of anti-peeping sub-pixels, and is configured to encapsulate the plurality of display sub-pixels and the plurality of anti-peeping sub-pixels. The plurality of light-shielding layers are respectively disposed on the plurality of anti-peeping sub-pixels. Each light-shielding layer is configured to block an emitted light ray emitted perpendicularly to the substrate from the corresponding anti-peeping sub-pixel. The encapsulation layer includes an organic encapsulation layer and a first inorganic encapsulation layer. The first inorganic encapsulation layer is disposed on a side of the organic encapsulation layer facing away from the substrate. In an area where each anti-peeping sub-pixel is located, at least one refractive surface is formed on a side of the organic encapsulation layer that faces towards the first inorganic encapsulation layer. The at least one refractive surface is configured to refract a portion of light emitted from the anti-peeping sub-pixel toward the corresponding light-shielding layer, such that the refracted light exits from at least one adjacent aperture region.

In some embodiments, an angle between each refractive surface and an emitted light ray that is emitted perpendicularly to the substrate from the corresponding anti-peeping sub-pixel lies within a first angular range, where the first angular range is greater than 0 degrees and less than 90 degrees.

In some embodiments, in an area where each anti-peeping sub-pixel is located, a refractive index of the first inorganic encapsulation layer is greater than a refractive index of the organic encapsulation layer. The refractive index of the first inorganic encapsulation layer lies between 1.7 and 1.9, and the refractive index of the organic encapsulation layer lies between 1.4 and 1.5.

In some embodiments, the organic encapsulation layer includes a groove at a position corresponding to each aperture region. A width of the groove is greater than a width of the aperture region. An orthographic projection of the groove on the substrate partially overlaps an orthographic projection of each adjacent light-shielding layer on the substrate. A side wall of the groove is inclined toward the adjacent anti-peeping sub-pixel, and the side wall serves as the at least one refractive surface.

In some embodiments, each refractive surface is a curved surface. A direction of a normal line at different positions on each refractive surface varies.

In some embodiments, in an area where each anti-peeping sub-pixel is located, at least one protrusion is formed on the organic encapsulation layer. A side of each protrusion facing towards the first inorganic encapsulation layer is a curved surface, serving as the at least one refractive surface.

In some embodiments, the encapsulation layer further includes a first organic refractive layer, which is disposed between the organic encapsulation layer and the first inorganic encapsulation layer. A refractive index of the first organic refractive layer is higher than a refractive index of the organic encapsulation layer.

In some embodiments, a side of the first organic refractive layer facing towards the first inorganic encapsulation layer is a flat surface. A film layer interface of the first organic refractive layer facing towards the anti-peeping sub-pixel matches a shape of the at least one refractive surface.

In some embodiments, in an area where each anti-peeping sub-pixel is located, a thickness of the corresponding light-shielding layer gradually decreases in a direction from a central region of the anti-peeping sub-pixel toward a periphery thereof.

The present application further discloses a display device, which includes a driving circuit and the above-described display panel, where the driving circuit is configured to drive the display panel to display.

In the present application, at least one refractive surface is disposed in each anti-peeping sub-pixel region. When the anti-peeping light ray of each anti-peeping sub-pixel is emitted, due to the refraction effect of the at least one refractive surface, as many anti-peeping light rays as possible can exit from one or more adjacent aperture regions. That is, the emitted light ray perpendicular to the substrate from each anti-peeping sub-pixel is refracted by the refraction effect, thereby exiting from one or more adjacent aperture regions to achieve an anti-peeping effect, thus improving the light utilization rate of the anti-peeping sub-pixel. Moreover, the present application improves the film layer interface between the first inorganic encapsulation layer and the organic encapsulation layer in the encapsulation layer without requiring additional structures, such that the film layer interface between the first inorganic encapsulation layer and the organic encapsulation layer forms at least one refractive surface. This allows a portion of light emitted from each anti-peeping sub-pixel toward the corresponding light-shielding layer to be refracted and exit from one or more adjacent aperture regions, thereby enhancing the brightness and anti-peeping effect of the anti-peeping sub-pixel at the anti-peeping viewing angle, while reducing improvement costs.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a top schematic view of a display panel according to a first embodiment of the present application.

FIG. 2 is a cross-sectional schematic view of the display panel according to the first embodiment of the present application.

FIG. 3 is a schematic diagram of luminous intensity at different angles of an anti-peeping sub-pixel without a refractive surface and of a display sub-pixel according to the present application.

FIG. 4 is a schematic diagram of luminous intensity at different angles of an anti-peeping sub-pixel and a display sub-pixel according to the first embodiment of the present application.

FIG. 5 is a schematic diagram of another display panel according to the first embodiment of the present application.

FIG. 6 is a schematic diagram of yet another display panel according to the first embodiment of the present application.

FIG. 7 is a schematic diagram of a display panel according to a second embodiment of the present application.

FIG. 8 is a schematic diagram of another display panel according to the second embodiment of the present application.

FIG. 9 is a schematic diagram of a display panel according to a third embodiment of the present application.

FIG. 10 is a schematic diagram of a display device according to the present application.

In the drawings: 100, display panel; 101, aperture region; 102, non-aperture region; 111, substrate; 112, pixel defining layer; 120, display sub-pixel; 130, anti-peeping sub-pixel; 140, encapsulation layer; 141, first inorganic encapsulation layer; 142, organic encapsulation layer; 1421, refractive surface; 1422, protrusion; 1423, groove; 143, second inorganic encapsulation layer; 144, first organic refractive layer; 150, light-shielding layer; 200, display device; 210, driving circuit.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms "first", "second", or the like are merely used for illustrative purposes, and shall not be construed as indicating relative importance or implicitly indicating the number of technical features specified. Thus, unless otherwise specified, the features defined by "first" and "second" may explicitly or implicitly include one or more of such features. Terms "multiple", "a plurality of", and the like mean two or more. In addition, terms "up", "down", "left", "right", "vertical", and "horizontal", or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application will be described in detail below with reference to the accompanying drawings and some optional embodiments.

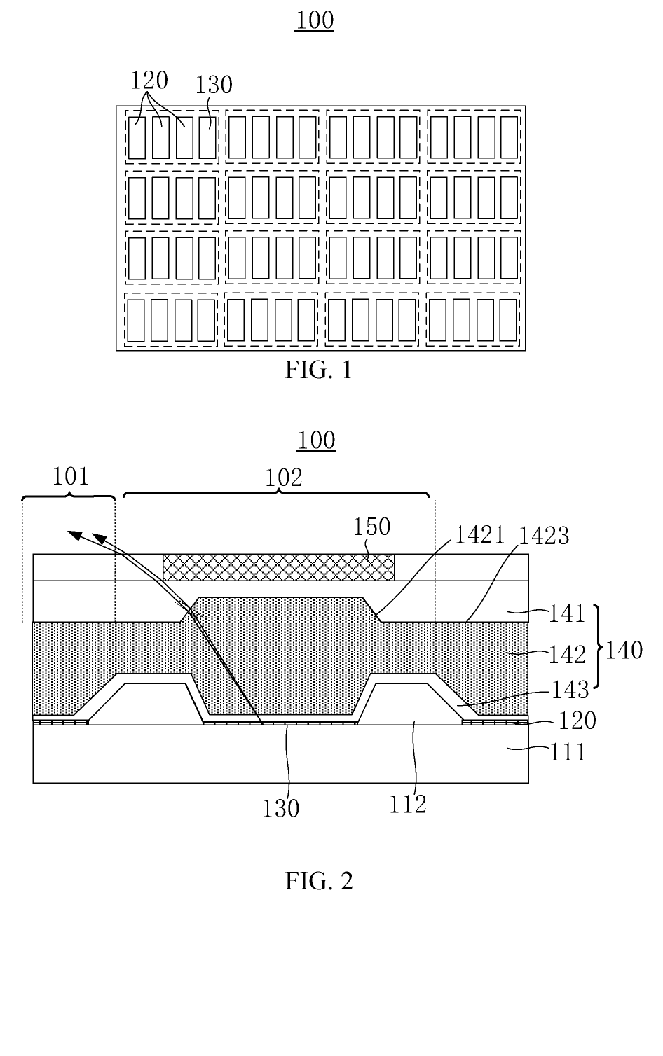

FIG. 1 is a top schematic view of a display panel according to a first embodiment of the present application. FIG. 2 is a cross-sectional schematic view of the display panel according to the first embodiment of the present application. Referring to FIGS. 1 and 2, the present application discloses a display panel 100. The display panel 100 includes a plurality of aperture regions 101 and a plurality of non-aperture regions 102. The display panel 100 further includes a substrate 111, a pixel defining layer 112, a plurality of display sub-pixels 120, a plurality of anti-peeping sub-pixels 130, an encapsulation layer 140, and a plurality of light-shielding layers 150. The pixel defining layer 112 is disposed on the substrate 111 and located in the plurality of non-aperture regions 102. Each display sub-pixel 120 is disposed within a corresponding aperture region 101. Two adjacent display sub-pixels 120 are separated from each other by the pixel defining layer 112. The plurality of anti-peeping sub-pixels 130 are respectively disposed in the plurality of non-aperture regions 102. At least one anti-peeping sub-pixel 130 is disposed within each pixel, and the anti-peeping sub-pixel 130 is separated from each adjacent display sub-pixel 120 by the pixel defining layer 112. The encapsulation layer 140 is disposed on the pixel defining layer 112, the plurality of display sub-pixels 120, and the plurality of anti-peeping sub-pixels 130 and configured to encapsulate the plurality of display sub-pixels 120 and the plurality of anti-peeping sub-pixels 130. The plurality of light-shielding layers 150 are respectively disposed on the plurality of anti-peeping sub-pixels 130, and each light-shielding layer is configured to block emitted light rays emitted perpendicularly to the substrate 111 from the corresponding anti-peeping sub-pixel 130. The encapsulation layer 140 includes an organic encapsulation layer 142 and a first inorganic encapsulation layer 141. The first inorganic encapsulation layer 141 is disposed on a side of the organic encapsulation layer 142 facing away from the substrate 111. In an area where each anti-peeping sub-pixel 130 is located, at least one refractive surface 1421 is formed on a side of the organic encapsulation layer 142 facing towards the first inorganic encapsulation layer 141. The at least one refractive surface 1421 is configured to refract a portion of light emitted from the anti-peeping sub-pixel 130 toward the corresponding light-shielding layer 150, such that the refracted light exits from at least one adjacent aperture region 101.

In the present application, at least one refractive surface 1421 is disposed in an area of each anti-peeping sub-pixel 130. When anti-peeping light rays are emitted from the anti-peeping sub-pixel 130, due to the refraction effect of the at least one refractive surface 1421, as many anti-peeping light rays as possible can exit from at least one adjacent aperture region 101. That is, the emitted light ray perpendicular to the substrate 111 from each anti-peeping sub-pixel 130 is refracted by the refraction effect, thereby exiting from at least one adjacent aperture region 101, achieving an anti-peeping effect and thus improving the light utilization rate of each anti-peeping sub-pixel 130. Moreover, the present application improves the film layer interface between the first inorganic encapsulation layer 141 and the organic encapsulation layer 142 in the encapsulation layer 140, so that no additional structures are required. The film layer interface between the first inorganic encapsulation layer 141 and the organic encapsulation layer 142 forms at least one refractive surface 1421, which refracts a portion of light emitted from each anti-peeping sub-pixel 130 toward the corresponding light-shielding layer 150, allowing the refracted light to exit from at least one adjacent aperture region 101 or from regions within the corresponding non-aperture region 102 that are not blocked by the light-shielding layer 150. This enhances the brightness and anti-peeping effect of each anti-peeping sub-pixel 130 at the anti-peeping viewing angle, while reducing improvement costs.

The direction perpendicular to the substrate 111 may be a normal line direction of the display panel 100. A wide viewing angle display panel 100 has a viewing angle of about 160 degrees, that is, the angle between the emitted light ray and the normal line direction of the display panel 100 can be up to 80 degrees. A display panel 100 may have a viewing angle of about 120 degrees, that is, the angle between the emitted light ray and the normal line direction of the display panel 100 can be up to 60 degrees. For anti-peeping, interference is required when the angle between the emitted light ray and the normal line direction of the display panel 100 exceeds 25 degrees. That is, the angle between the emitted light ray and the normal line direction of the display panel 100 in the range of 0 to 25 degrees is defined as a front viewing angle, and the range exceeding 25 degrees is defined as an anti-peeping viewing angle. Light emitted from each anti-peeping sub-pixel 130 in the range exceeding 25 degrees causes the gray scale of each display sub-pixel to vary and phenomena such as color mixing to occur at the anti-peeping viewing angle, thereby making the displayed content indistinguishable at the anti-peeping viewing angle thus achieving the anti-peeping effect. However, since most of the perpendicularly emitted light from each anti-peeping sub-pixel 130 is blocked by the corresponding light-shielding layer 150, the light utilization rate at the anti-peeping viewing angle is relatively low. It is worth mentioning that each light-shielding layer 150 needs to completely block the perpendicularly emitted light from the corresponding anti-peeping sub-pixel 130; therefore, an area of each light-shielding layer 150 is larger than the light-emitting area of the corresponding anti-peeping sub-pixel 130. However, the area of each light-shielding layer 150 can be reduced to be smaller than the area of the corresponding non-aperture region 102. That is, the orthographic projection of each light-shielding layer 150 on the substrate 111 lies within a range of an orthographic projection of a corresponding portion of the pixel defining layer 112 on the substrate 111. Therefore, the above-mentioned anti-peeping light rays can exit through at least one adjacent aperture region 101 or an unblocked area within the corresponding non-aperture region 102 after refraction.

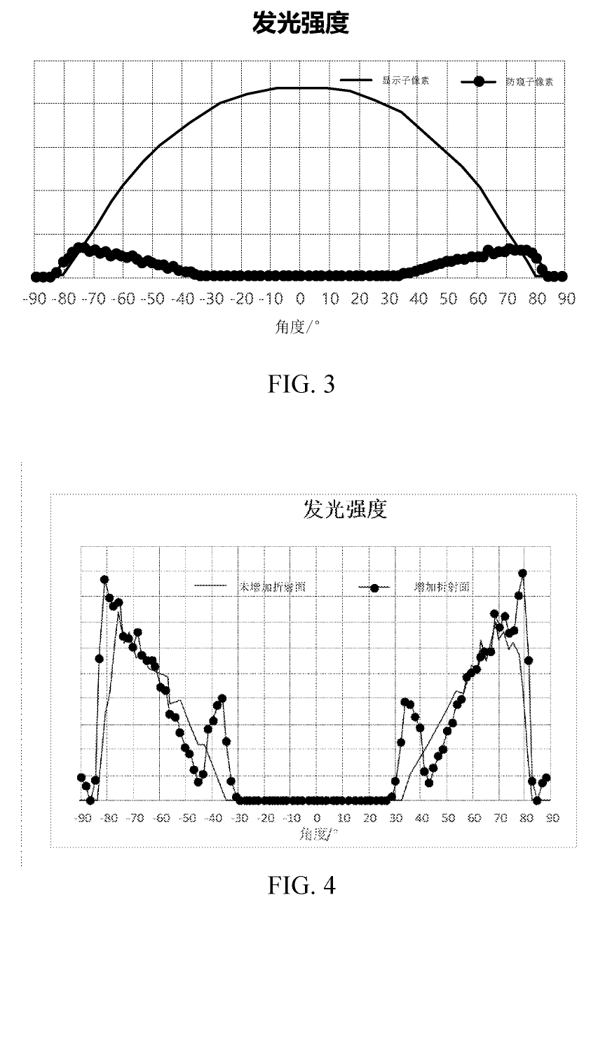

FIG. 3 is a schematic diagram of the luminous intensity at different angles of an anti-peeping sub-pixel without a refractive surface and a display sub-pixel according to the present application. Referring to FIG. 3, together with FIGS. 1 and 2, the x-coordinate represents an angle measured from an emitted light ray of each of the anti-peeping sub-pixel 130 and the display sub-pixel 120 to a normal line of the display panel 100, and the y-coordinate represents the intensity of the emitted light rays of the anti-peeping sub-pixel 130 and the display sub-pixel 120 at the corresponding angle. Currently, when both the anti-peeping sub-pixel 130 and the display sub-pixel 120 each adopt a light-emitting element structure and are formed at the openings of the pixel defining layer 112, that is, when the light-emitting layers of the anti-peeping sub-pixel 130 and the display sub-pixel 120 are simultaneously fabricated by vapor deposition, their light-emitting efficiencies are similar. As the above-mentioned angle gradually increases, the luminous intensity of the anti-peeping sub-pixel 130 gradually decreases. However, since the present application utilizes the emitted light rays of the anti-peeping sub-pixel 130 at the anti-peeping viewing angle, especially the anti-peeping light rays between 25 degrees and 45 degrees are seriously insufficient, this results in poor anti-peeping performance.

Continuing to refer to FIG. 2, the present application improves the refractive index of the film layers and the film layer interface within the encapsulation layer 140, such that the film layer interface between, for example, the first inorganic encapsulation layer 141 and the organic encapsulation layer 142 forms at least one refractive surface 1421, thereby enhancing the anti-peeping light rays of each anti-peeping sub-pixel 130 within the range of 25 degrees to 45 degrees. The organic encapsulation layer 142 in the encapsulation layer 140 may be formed of an organic insulating material and has a relatively large thickness. The film layer interface of the organic encapsulation layer 142 facing the side of the first inorganic encapsulation layer 141 is relatively flat and is substantially parallel to the substrate 111. In the present embodiment, at least one refractive surface 1421 is required to be non-parallel to the substrate 111, and forms an angle with the emitted light ray emitted perpendicularly from the corresponding anti-peeping sub-pixel 130 (referred to as perpendicularly emitted light). Through refraction, a portion of the perpendicularly emitted light is refracted to one or more adjacent aperture regions 101, thereby enhancing the brightness of the emitted light rays of the anti-peeping sub-pixel 130 within the range of 25 degrees to 45 degrees, and thus improving the anti-peeping capability.

Specifically, the angle between each refractive surface 1421 and the emitted light ray emitted perpendicularly from the corresponding anti-peeping sub-pixel 130 to the substrate 111 lies within a first angular range, where the first angular range is greater than 0 degrees and less than 90 degrees. When the perpendicularly emitted light emitted from the anti-peeping sub-pixel 130 is incident at an angle on the at least one refractive surface 1421, due to the difference in refractive indices between the organic encapsulation layer 142 and the first inorganic encapsulation layer 141, the perpendicularly emitted light from the anti-peeping sub-pixel 130 would be refracted by the at least one refractive surface 1421. This refraction changes the emission angle of the perpendicularly emitted light, enabling the perpendicularly emitted light to exit from at least one adjacent aperture region 101 where a display sub-pixel 120 is located, thereby achieving the anti-peeping effect.

In one embodiment, in each region of the anti-peeping sub-pixel 130, the refractive index of the first inorganic encapsulation layer 141 is greater than that of the organic encapsulation layer 142. When the refractive index of the first inorganic encapsulation layer 141 is relatively larger, light entering from the organic encapsulation layer 142 into the first inorganic encapsulation layer 141 may be refracted toward the normal line direction of the refractive surface 1421. If it is desired for these light rays to exit from one or more corresponding aperture regions 101, the angle of each refractive surface 1421 may be adjusted accordingly. For example, each refractive surface 1421 may be inclined toward the corresponding anti-peeping sub-pixel 130 such that the angle between the normal line of the refractive surface 1421 and the substrate 111 is within a range of 30 degrees to 60 degrees. This allows a portion of the perpendicularly emitted light from the corresponding anti-peeping sub-pixel 130 to exit through one or more adjacent aperture regions 101, thereby increasing the light intensity within the anti-peeping viewing angle range of 25 degrees to 45 degrees. In the above description, the inclination of each refractive surface 1421 toward the anti-peeping sub-pixel 130 means that, along the direction from the center of the anti-peeping sub-pixel 130 toward its outer edge, the height of each refractive surface 1421 gradually decreases, i.e., it slopes downward. Conversely, along the direction from the outer edge of the anti-peeping sub-pixel 130 toward the center of the anti-peeping sub-pixel 130, the height of each refractive surface 1421 gradually increases, that is, it slopes upward.

Specifically, in the thin-film encapsulation technique, the encapsulation layer 140 may be formed by stacking an inorganic insulating material and an organic insulating material. The encapsulation layer 140 may include a first inorganic encapsulation layer 141, an organic encapsulation layer 142, and a second inorganic encapsulation layer 143. The second inorganic encapsulation layer 143 is disposed on the plurality of anti-peeping sub-pixels 130 and the plurality of display sub-pixels 120. The organic encapsulation layer 142 is disposed on the second inorganic encapsulation layer 143. The first inorganic encapsulation layer 141 and the second inorganic encapsulation layer 143 are each formed of an inorganic insulating material. The organic encapsulation layer 142 is formed of an organic insulating material. In the present embodiment, the difference in refractive index between the organic encapsulation layer 142 and the first inorganic encapsulation layer 141 is primarily utilized. Moreover, the organic encapsulation layer 142 has a relatively large thickness, facilitating the formation of the refractive surface 1421 thereon, thereby enhancing the anti-peeping light rays of each anti-peeping sub-pixel 130 at large viewing angles.

Specifically, the refractive index of the first inorganic encapsulation layer 141 lies between 1.7 and 1.9, and the refractive index of the organic encapsulation layer 142 lies between 1.4 and 1.5.

In another embodiment, when the materials used result in the refractive index of the organic encapsulation layer 142 being higher than that of the first inorganic encapsulation layer 141, the tilt angle of the refractive surface 1421 can be adjusted such that the tilt angle tilts away from the direction of the anti-peeping sub-pixel 130. In this manner, the at least one refractive surface 1421 can also refract the perpendicularly emitted light of the anti-peeping sub-pixel 130 to one or more corresponding aperture regions 101. The description "the tilt angle of the refractive surface 1421 tilts away from the direction of the anti-peeping sub-pixel 130" means that, on the basis of the above configuration where the refractive index of the organic encapsulation layer 142 is less than that of the first inorganic encapsulation layer 141, and the refractive surface 1421 is already inclined toward the anti-peeping sub-pixel 130, the slope of the refractive surface 1421 becomes steeper, or the inclined surface rotates toward a more vertical orientation, thereby making the inclined surface steeper, which results in the effect of the tilt angle of the refractive surface 1421 tilting away from the anti-peeping sub-pixel 130.

Specifically, each refractive surface 1421 in the present embodiment may be a flat surface with a single slope or a curved surface with a varying slope, so as to enhance the anti-peeping light rays at a fixed angle or varying angles.

Referring again to FIG. 2, in the present embodiment, each refractive surface 1421 is a flat surface, and the direction of the normal line at every point on the refractive surface 1421 is the same.

In the present embodiment, the organic encapsulation layer 142 includes a groove 1423 at the position corresponding to each aperture region 101. The width of the groove 1423 is greater than the width of the aperture region 101. The orthographic projection of the groove 1423 on the substrate 111 partially overlaps the orthographic projection of the adjacent light-shielding layer 150 on the substrate 111. The side wall of the groove 1423 is inclined toward the corresponding anti-peeping sub-pixel 130, and the side wall serves as the refractive surface 1421.

In the above description, the expression "the side wall of the groove 1423 is inclined toward the corresponding anti-peeping sub-pixel 130" means that, along the direction from the groove 1423 toward the corresponding anti-peeping sub-pixel 130, the height of the side wall of the groove 1423 gradually increases, that is, it slopes upward. Conversely, along the direction from the corresponding anti-peeping sub-pixel 130 toward the groove 1423, the height of the side wall of the groove 1423 gradually decreases, that is, it slopes downward.

In this solution, a groove 1423 may be defined in the organic encapsulation layer 142 at the position of each aperture region 101, such that the side wall of the groove 1423 has a certain tilt angle and serves as the at least one refractive surface 1421, thereby achieving the purpose of refracting the perpendicularly emitted light emitted from the corresponding anti-peeping sub-pixel 130. It is understood that the anti-peeping light rays emitted from each anti-peeping sub-pixel 130, after being refracted by the at least one refractive surface 1421, still need to pass through the planarization layer before entering the air. Since these anti-peeping light rays are not perpendicularly incident into the planarization layer, they may pass through the planarization layer at a certain angle. Especially when entering the air from the planarization layer, refraction will occur again, thereby enhancing the anti-peeping capability within the anti-peeping viewing angle range of 25 degrees to 45 degrees.

FIG. 4 is a schematic diagram showing the luminous intensity of an anti-peeping sub-pixel and a display sub-pixel at different angles according to the first embodiment of the present application. Referring to FIG. 4, and in conjunction with FIGS. 1 and 2, at least one refractive surface 1421 is formed by defining a groove 1423 in the organic encapsulation layer 142. Each refractive surface 1421 forms an angle with the substrate 111 in the range of 30 degrees to 60 degrees. The refractive index of the first inorganic encapsulation layer 141 is set between 1.7 and 1.9, and the refractive index of the organic encapsulation layer 142 is between 1.4 and 1.5. It can be seen that when the anti-peeping viewing angle is in the range of 30 degrees to 45 degrees, the light-emitting brightness of each anti-peeping sub-pixel 130 is significantly enhanced, thereby greatly improving the anti-peeping capability at this anti-peeping viewing angle range.

It is worth mentioning that, in actual design, the thickness of the organic encapsulation layer 142, the depth of the groove 1423, the inclination degree of the side wall of the groove 1423, and the refractive indices may be comprehensively considered. By adjusting the above parameters, the intensity of the anti-peeping light rays within the anti-peeping viewing angle range of 25 degrees to 60 degrees can be greatly enhanced.

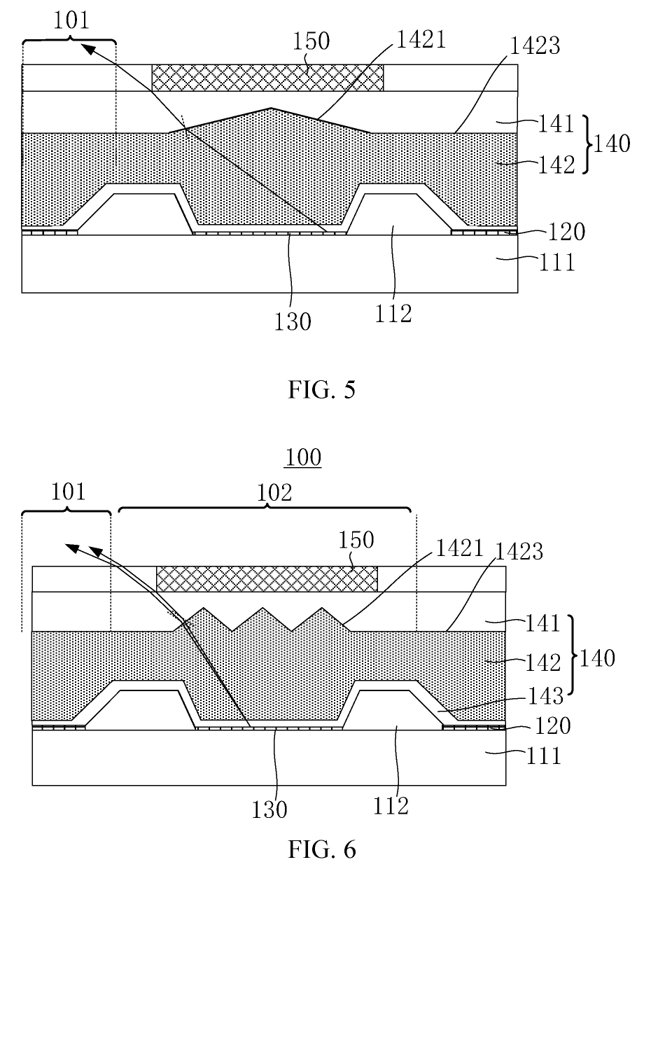

FIG. 5 is a schematic diagram of another display panel according to the first embodiment of the present application. Referring to FIG. 5, and also in conjunction with FIGS. 1 and 2, in another design, the side walls of adjacent grooves 1423 within the region of each anti-peeping sub-pixel 130 can be connected to each other by improving the side walls of the groove 1423, thereby allowing more perpendicularly emitted light to be refracted and emitted through the aperture region 101.

In this embodiment, the organic encapsulation layer 142 in the region where each anti-peeping sub-pixel 130 is located is formed with refractive surfaces 1421 inclined toward the anti-peeping sub-pixel 130, wherein the inclination directions of two adjacent refractive surfaces 1421 differ, but the extension directions of their normal lines each pass through the anti-peeping sub-pixel 130. When the angle formed between each refractive surface 1421 and the substrate 111 increases, the required thickness of the organic encapsulation layer 142 also increases, which is of course also related to the area of the anti-peeping sub-pixel 130.

FIG. 6 is a schematic diagram of another display panel according to the first embodiment of the present application. Referring to FIG. 6, in the area of each anti-peeping sub-pixel 130, the surface of the organic encapsulation layer 142 facing towards the first inorganic encapsulation layer 141 may be formed into a triangular shape. That is, multiple triangular protrusions may be formed on the organic encapsulation layer 142, thereby forming multiple refractive surfaces 1421.

Compared with the above embodiment, when the side wall of the groove 1423 serves as the refractive surface 1421, the utilization rate of the perpendicularly emitted light from the corresponding anti-peeping sub-pixel 130 is still low. Only the perpendicularly emitted light from the outer edge of the anti-peeping sub-pixel 130 can be refracted, while the perpendicularly emitted light from the central area of the anti-peeping sub-pixel 130 may still be emitted onto the corresponding light-shielding layer 150. By setting the film layer interface of the organic encapsulation layer 142 in the area of each anti-peeping sub-pixel 130 entirely as inclined slopes, the emitted light rays from the anti-peeping sub-pixel 130 are diffused. The orthographic projection range of the plurality of refractive surfaces 1421 on the substrate 111 may be within the orthographic projection range of the corresponding light-shielding layer 150 on the substrate 111, thereby avoiding light leakage issues. In this embodiment, the triangular film layer may be formed by a templating method, that is, after pre-curing the organic encapsulation layer 142, the triangular film layer may be formed by transfer molding.

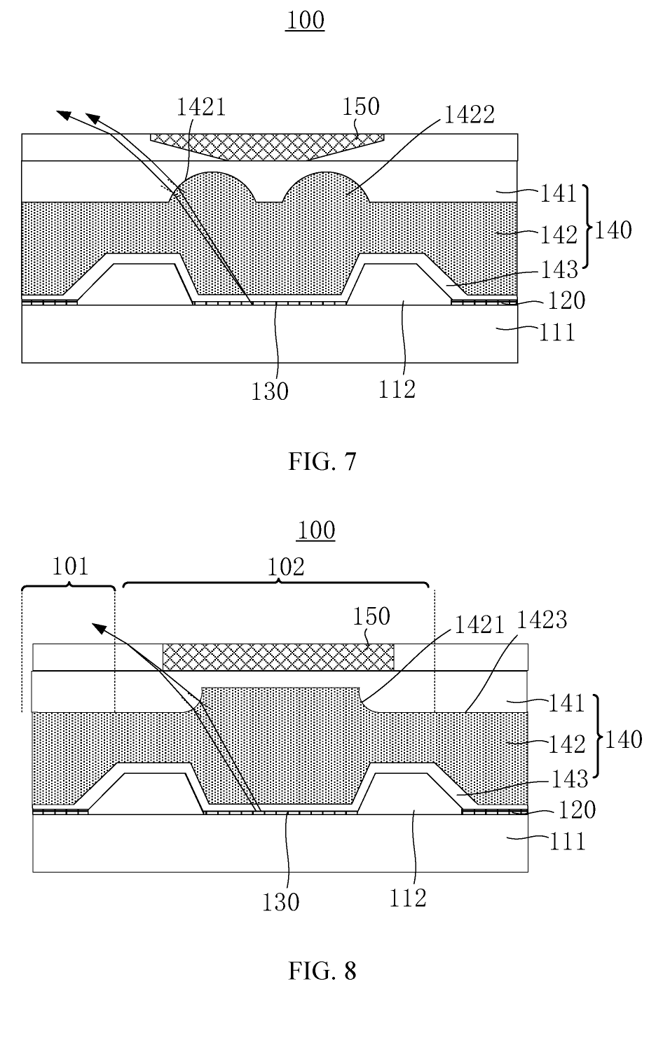

FIG. 7 is a schematic diagram of a display panel according to a second embodiment of the present application. Referring to FIG. 7, in this embodiment, each refractive surface 1421 may be formed as a curved surface, so that the direction of the normal line at each position gradually changes, thereby achieving more uniform light emission. The directions of the normal lines at different positions of each refractive surface 1421 differ, causing the offset amount of the perpendicularly emitted light from the corresponding anti-peeping sub-pixel 130 to vary at different positions. As a result, the emitted light from the anti-peeping sub-pixel 130 becomes more divergent after passing through, and the anti-peeping light rays at various angles become more uniform, thereby achieving better anti-peeping effect.

Specifically, in the area where the anti-peeping sub-pixel 130 is located, at least one protrusion 1422 is formed on the organic encapsulation layer 142. Each protrusion 1422 has a curved surface on the side facing the first inorganic encapsulation layer 141, serving as a refractive surface 1421. Since the direction of the normal line at each position of the curved surface is different and gradually changes, when the perpendicularly emitted light irradiates different positions of the refractive surface 1421, although the ratio of refractive indices between the organic encapsulation layer 142 and the first inorganic encapsulation layer 141 remains unchanged, the offset amount of the perpendicularly emitted light toward the normal line remains constant. However, with the gradual change of the normal line direction, the final emission direction of the perpendicularly emitted light also gradually varies, thereby making the anti-peeping light rays more uniform. Moreover, by setting the curvature of each protrusion 1422, varying angle enhancement of the anti-peeping light rays can be achieved. The protrusion 1422 may be arranged in one or multiple. In this embodiment, two protrusions 1422 are provided as an example, and the refractive surface 1421 of each protrusion 1422 is a curved surface, with its curvature designed depending on actual conditions.

The curved surface of each protrusion 1422 can be realized by a half-tone photolithography technique, making the top surface of the protrusion 1422 a curved surface, thereby achieving a refraction effect on the anti-peeping light rays.

For each light-shielding layer 150 in this embodiment, in the region corresponding to each anti-peeping sub-pixel 130, the thickness of the light-shielding layer 150 gradually decreases from the central area towards the periphery.

Considering that the anti-peeping light rays are emitted at a certain inclined angle, in practice, the bottom of each light-shielding layer 150 can be designed with a tilt angle based on the angle of the emitted light rays, so that the cross-section of the light-shielding layer 150 forms an inverted triangular shape. Of course, the edge regions of the light-shielding layer 150 also have a certain thickness sufficient to provide a light-shielding effect. For schemes where the light-shielding layer 150 is relatively thin, the thickness of the light-shielding layer 150 can be appropriately increased, so that within the region corresponding to the anti-peeping sub-pixel 130, the thickness of the light-shielding layer 150 gradually decreases from the central area towards the periphery. Additionally, by disposing a reflective layer on the side of the light-shielding layer 150 facing towards the anti-peeping sub-pixel 130, the portion of the perpendicularly emitted light that cannot be refracted by the at least one refractive surface 1421 can be reflected to one or more corresponding aperture regions 101, thereby enhancing the brightness of the anti-peeping light rays. However, this requires adding an additional reflective layer, increasing implementation complexity and making the film structure more complicated. Of course, this scheme can be applied to the display panel 100 of any of the above embodiments. When the display panel 100 is an Organic Light-Emitting Diode (OLED) display panel using Color Filter on Encapsulation (COE) technology, the light-shielding layer 150 in this embodiment may be shared as the black matrix.

FIG. 8 is a schematic diagram of another display panel according to the second embodiment of the present application. As shown in FIG. 8, in this embodiment, the organic encapsulation layer 142 includes a groove 1423 at the position corresponding to each aperture region 101. The width of the groove 1423 is greater than the width of the aperture region 101. The orthographic projection of the groove 1423 on the substrate 111 partially overlaps the orthographic projection of the adjacent light-shielding layer 150 on the substrate 111. The side wall of the groove 1423 is configured as a concave curved surface, and this curved surface serves as the refractive surface 1421. Here, the side wall of the groove 1423 being configured as a concave curved surface means that the side wall has a convex shape on the side facing the corresponding anti-peeping sub-pixel 130, and a concave shape on the side facing the groove 1423.

Different from the previous embodiment, in this embodiment, no protrusion 1422 is disposed. Instead, based on the groove 1423 defined in the organic encapsulation layer 142 located within each aperture region 101, the side wall of the groove 1423 is etched to have a curved surface with a certain curvature, thereby forming a curved refractive surface 1421. This achieves refraction of the perpendicularly emitted light, allowing this portion of light to be emitted from the corresponding aperture region 101 at a certain angle.

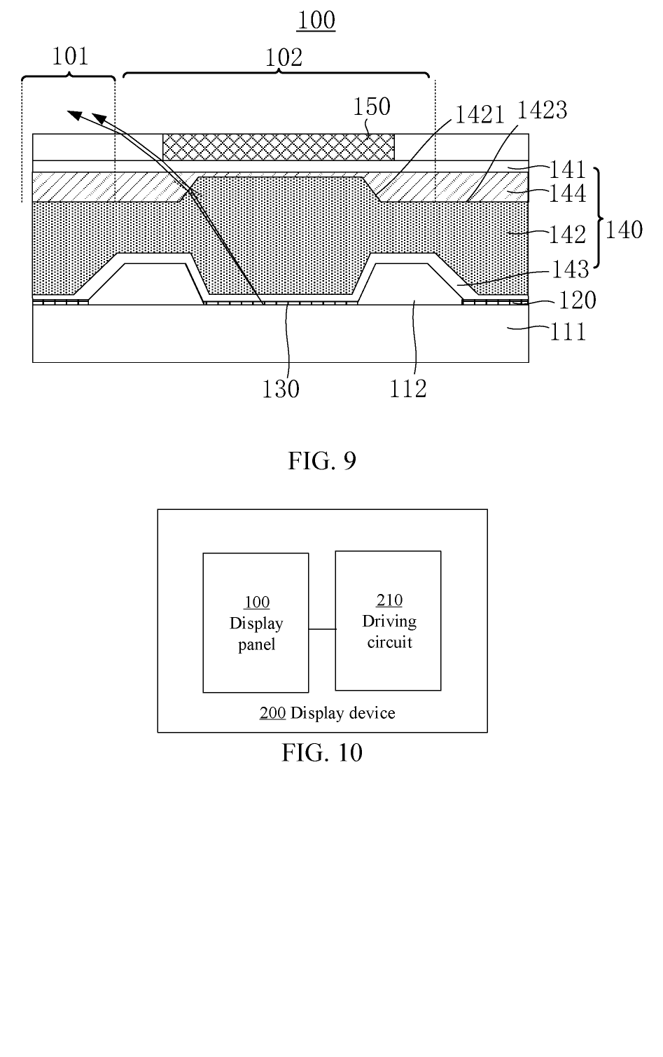

FIG. 9 is a schematic diagram of a display panel according to a third embodiment of the present application. Referring to FIG. 9, considering that forming the refractive surface 1421 on the organic encapsulation layer 142 as described above inevitably causes the film layer interface on the side of the organic encapsulation layer 142 facing the first inorganic encapsulation layer 141 to become uneven, it is necessary to select a thicker first inorganic encapsulation layer 141 to planarize that part of the film layer. However, when the first inorganic encapsulation layer 141 is relatively thick, cracks are prone to appear, which can lead to moisture and oxygen intrusion into the encapsulation layer 140, posing a risk of poor encapsulation.

In this regard, in the present embodiment, the encapsulation layer 140 further includes a first organic refractive layer 144, which is disposed between the organic encapsulation layer 142 and the first inorganic encapsulation layer 141. The refractive index of the first organic refractive layer 144 is higher than that of the organic encapsulation layer 142.

In this embodiment, the first organic refractive layer 144 may be made of an organic insulating material. However, its refractive index needs to be higher than that of the organic encapsulation layer 142, so that when light is emitted, the light can deviate from the direction of the normal line, enabling the light to exit through one or more corresponding aperture regions 101. The first organic refractive layer 144 has a certain buffering capability and can cover the uneven refractive surface 1421 formed by the organic encapsulation layer 142, thereby improving issues such as cracks present between the refractive surface 1421 and the first inorganic encapsulation layer 141, thus enhancing the quality of the first inorganic encapsulation layer 141.

In a specific embodiment, the refractive index of the first organic refractive layer 144 lies between the refractive indices of the organic encapsulation layer 142 and the first inorganic encapsulation layer 141, thereby causing a refraction effect again between the first organic refractive layer 144 and the first inorganic encapsulation layer 141, thus increasing the brightness of the anti-peeping light rays within the anti-peeping viewing angle.

FIG. 10 is a schematic diagram of a display device according to the present application. Referring to FIG. 10, the present application further discloses a display device 200. The display device 200 includes a driving circuit 210 and the display panel 100 according to any one of the above embodiments, where the driving circuit 210 is configured to drive the display panel 100 for display.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling within the scope of protection of the present application.

What is claimed is:

1. A display panel, comprising a plurality of aperture regions and a plurality of non-aperture regions, the display panel further comprising:
a substrate;
a pixel defining layer, disposed on the substrate and located in the plurality of non-aperture regions;
a plurality of display sub-pixels, respectively disposed within the plurality of aperture regions, wherein every two adjacent display sub-pixels are separated by the pixel defining layer;
a plurality of anti-peeping sub-pixels, respectively disposed within the plurality of non-aperture regions, wherein at least one anti-peeping sub-pixel is disposed within each pixel of the display panel, and wherein each of the plurality of anti-peeping sub-pixels is separated from each adjacent display sub-pixel by the pixel defining layer;
an encapsulation layer, disposed on the pixel defining layer, the plurality of display sub-pixels, and the plurality of anti-peeping sub-pixels; wherein the encapsulation layer is configured to seal the plurality of display sub-pixels and the plurality of anti-peeping sub-pixels; and
a plurality of light-shielding layers, respectively disposed on the plurality of anti-peeping sub-pixels; wherein each of the plurality of light-shielding layers is configured to block an emitted light ray that is perpendicular to the substrate and emitted from a corresponding anti-peeping sub-pixel;
wherein the encapsulation layer comprises an organic encapsulation layer and a first inorganic encapsulation layer disposed on a side of the organic encapsulation layer facing away from the substrate;
wherein in an area corresponding to each anti-peeping sub-pixel, a side of the organic encapsulation layer facing towards the first inorganic encapsulation layer comprises at least one refractive surface, the at least one refractive surface being configured to refract a portion of light emitted from the anti-peeping sub-pixel toward a corresponding light-shielding layer, thus allowing refracted light to exit through at least one adjacent aperture region.

2. The display panel as recited in claim 1, wherein each of the at least one refractive surface forms an angle with the emitted light ray that is perpendicular to the substrate and that is emitted from the corresponding anti-peeping sub-pixel, the angle lying within a first angular range, and
wherein the first angular range is greater than 0 degrees and less than 90 degrees.

3. The display panel as recited in claim 1, wherein within an area where each of the plurality of anti-peeping sub-pixels is located, a refractive index of the first inorganic encapsulation layer is greater than a refractive index of the organic encapsulation layer;
wherein the refractive index of the first inorganic encapsulation layer lies between 1.7 and 1.9, and the refractive index of the organic encapsulation layer lies between 1.4 and 1.5.

4. The display panel as recited in claim 2, wherein the organic encapsulation layer comprises a groove at a position corresponding to each of the plurality of aperture regions, wherein a width of the groove is greater than a width of the aperture region, wherein an orthographic projection of the groove on the substrate partially overlaps an orthographic projection of each adjacent light-shielding layer on the substrate;
wherein a side wall of the groove is inclined toward a corresponding adjacent anti-peeping sub-pixel, the side wall serving as the at least one refractive surface.

5. The display panel as recited in claim 2, wherein each of the at least one refractive surface is a curved surface, and wherein a normal line direction at different positions of each refractive surface is different.

6. The display panel as recited in claim 5, further comprising at least one protrusion disposed on the organic encapsulation layer within an area of each anti-peeping sub-pixel, wherein each of the at least one protrusion has a curved surface on a side facing towards the first inorganic encapsulation layer, the curved surface serving as the at least one refractive surface.

7. The display panel as recited in claim 2, wherein the encapsulation layer further comprises a first organic refractive layer disposed between the organic encapsulation layer and the first inorganic encapsulation layer,
wherein a refractive index of the first organic refractive layer is higher than that of the organic encapsulation layer.

8. The display panel as recited in claim 7, wherein a side of the first organic refractive layer adjacent to the first inorganic encapsulation layer is planar; and
wherein a surface of the first organic refractive layer facing towards each of the plurality of anti-peeping sub-pixels corresponds in shape to the at least one refractive surface disposed on the organic encapsulation layer.

9. The display panel as recited in claim 2, wherein within an area corresponding to each anti-peeping sub-pixel, a thickness of the corresponding light-shielding layer gradually decreases from a central region of the anti-peeping sub-pixel toward a periphery of the anti-peeping sub-pixel.

10. The display panel as recited in claim 2, wherein an angle measured from each of the at least one refractive surface to an emitted light ray emitted perpendicularly from the corresponding anti-peeping sub-pixel lies within a first angular range, wherein the first angular range is greater than or equal to 30 degrees and less than or equal to 60 degrees.

11. The display panel as recited in claim 3, wherein each of the at least one refractive surface is configured to enhance a brightness of emitted light rays of the corresponding anti-peeping sub-pixel within a range of 25 degrees to 45 degrees.

12. The display panel as recited in claim 1, wherein a light-emitting layer of each anti-peeping sub-pixel and a light-emitting layer of each display sub-pixel are formed in a same manufacturing procedure; and
wherein as an angle between an emitted light ray of each anti-peeping sub-pixel and a normal line of the display panel gradually increases, a luminous intensity of the anti-peeping sub-pixel gradually decreases.

13. The display panel as recited in claim 1, wherein within an area where each anti-peeping sub-pixel is located, a thickness of the corresponding light-shielding layer gradually decreases from a central region of the anti-peeping sub-pixel toward a periphery of the anti-peeping sub-pixel.

14. A display device, comprising a driving circuit and a display panel, wherein the driving circuit is configured to drive the display panel to display; wherein the display panel comprises a plurality of aperture regions and a plurality of non-aperture regions, and further comprises:
a substrate;
a pixel defining layer, disposed on the substrate and located in the plurality of non-aperture regions;
a plurality of display sub-pixels, respectively disposed within the plurality of aperture regions, wherein every two adjacent display sub-pixels are separated by the pixel defining layer;
a plurality of anti-peeping sub-pixels, respectively disposed within the plurality of non-aperture regions, wherein at least one anti-peeping sub-pixel is disposed within each pixel of the display panel, and wherein each of the plurality of anti-peeping sub-pixels is separated from each adjacent display sub-pixel by the pixel defining layer;
an encapsulation layer, disposed on the pixel defining layer, the plurality of display sub-pixels, and the plurality of anti-peeping sub-pixels; wherein the encapsulation layer is configured to seal the plurality of display sub-pixels and the plurality of anti-peeping sub-pixels; and
a plurality of light-shielding layers, respectively disposed on the plurality of anti-peeping sub-pixels; wherein each of the plurality of light-shielding layers is configured to block an emitted light ray that is perpendicular to the substrate and emitted from a corresponding anti-peeping sub-pixel;
wherein the encapsulation layer comprises an organic encapsulation layer and a first inorganic encapsulation layer disposed on a side of the organic encapsulation layer facing away from the substrate;
wherein in an area corresponding to each anti-peeping sub-pixel, a side of the organic encapsulation layer facing towards the first inorganic encapsulation layer comprises at least one refractive surface, the at least one refractive surface being configured to refract a portion of light emitted from the anti-peeping sub-pixel toward a corresponding light-shielding layer, thus allowing refracted light to exit through at least one adjacent aperture region.

15. The display device as recited in claim 14, wherein each of the at least one refractive surface forms an angle with the emitted light ray that is perpendicular to the substrate and that is emitted from the corresponding anti-peeping sub-pixel, the angle lying within a first angular range, and
wherein the first angular range is greater than 0 degrees and less than 90 degrees.

16. The display device as recited in claim 14, wherein within an area where each of the plurality of anti-peeping sub-pixels is located, a refractive index of the first inorganic encapsulation layer is greater than a refractive index of the organic encapsulation layer;
wherein the refractive index of the first inorganic encapsulation layer lies between 1.7 and 1.9, and the refractive index of the organic encapsulation layer lies between 1.4 and 1.5.

17. The display device as recited in claim 15, wherein the organic encapsulation layer comprises a groove at a position corresponding to each of the plurality of aperture regions, wherein a width of the groove is greater than a width of the aperture region, wherein an orthographic projection of the groove on the substrate partially overlaps an orthographic projection of each adjacent light-shielding layer on the substrate;
wherein a side wall of the groove is inclined toward a corresponding adjacent anti-peeping sub-pixel, the side wall serving as the at least one refractive surface.

18. The display device as recited in claim 15, wherein each of the at least one refractive surface is a curved surface, and wherein a normal line direction at different positions of each refractive surface is different.

19. The display device as recited in claim 18, further comprising at least one protrusion disposed on the organic encapsulation layer within an area of each anti-peeping sub-pixel, wherein each of the at least one protrusion has a curved surface on a side facing towards the first inorganic encapsulation layer, the curved surface serving as the at least one refractive surface.

20. The display device as recited in claim 15, wherein the encapsulation layer further comprises a first organic refractive layer disposed between the organic encapsulation layer and the first inorganic encapsulation layer,
wherein a refractive index of the first organic refractive layer is higher than that of the organic encapsulation layer.
